(19) United States
(12) Patent Application Publication
(10) Pub. No.: US 2024/0373728 A1
(43) Pub. Date: Nov. 7, 2024

(54) LIGHT EMITTING DEVICE AND ELECTRONIC DEVICE

(71) Applicant: SONY SEMICONDUCTOR SOLUTIONS CORPORATION, KANAGAWA (JP)

(72) Inventor: TOMOHIKO SHIMATSU, KANAGAWA (JP)

(21) Appl. No.: 18/562,672

(22) PCT Filed: May 31, 2022
(86) PCT No.: PCT/JP2022/022170

§ 371 Date: Nov. 20, 2023

(30) Foreign Application Priority Data
Jun. 11, 2021 (JP) 2021-098209

(51) Int. Cl. H10K 59/80; H10K 59/38

(52) U.S. Cl. CPC H10K 59/879; H10K 59/38

(57) ABSTRACT

Provided are a light emitting device and an electronic device excellent in suppression of laterally propagating light and stray light. The light emitting device includes a substrate; and a light emitter including, in order, a light emitting element, a lens layer, and a sealing layer that seals the light emitting element and the lens layer on the substrate, in which a light emitting region as a region where light generated from the light emitting element is emitted to the outside and a peripheral region as an outer region of the light emitting region are defined, in a case where a direction along a thickness direction of the light emitter is defined as a line-of-sight direction, and the light emitter is divided into a light emitting unit located in the light emitting region and a peripheral portion located in the peripheral region, at least a portion of the peripheral portion forms an inclined portion, at least a portion of the inclined portion satisfies a condition 1 or 2 and satisfies a condition 3, the condition 1 is that a thickness of the lens layer in the peripheral portion is smaller than a thickness of the lens layer in the light emitting unit, the condition 2 is that formation of the lens layer is avoided, and the condition 3 is that the thickness of the sealing layer in the peripheral portion is smaller than the thickness of the sealing layer in the light emitting unit, and a refractive index of the lens layer is larger than a refractive index of the sealing layer.

### TECHNICAL FIELD

The present disclosure relates to a light emitting device and an electronic device.

### BACKGROUND ART

As a light emitting device such as a display device, as shown in Patent Document 1, a light emitting device including a light emitting element including a light emitting stack disposed on a substrate and a light extraction layer stacked on a light emitting surface side of the light emitting element, in which light is extracted from the light emitting element to the outside through a path passing through the light extraction layer is known.

### CITATION LIST

### Patent Document

Patent Document 1: Japanese Patent Application Laid-Open No. 2014-504697

### SUMMARY OF THE INVENTION

### Problems to be Solved by the Invention

The light emitting device disclosed in Patent Document 1 has room for improvement in that light (laterally propagating light) laterally propagating by being reflected at an interface between the light extraction layer and another layer is emitted toward the outside of a display region and stray light is suppressed.

The present disclosure has been made in view of the above-described points, and an object of the present disclosure is to provide a light emitting device excellent in suppression of laterally propagating light and stray light, and an electronic device using the light emitting device.

### Solutions to Problems

The present disclosure is, for example, (1) a light emitting device including a substrate; and
a light emitter including, in order, a light emitting element, a lens layer, and a sealing layer that seals the light emitting element and the lens layer on the substrate,
in which a light emitting region as a region where light generated from the light emitting element is emitted to the outside and a peripheral region as an outer region of the light emitting region are defined,
in a case where a direction along a thickness direction of the light emitter is defined as a line-of-sight direction, and the light emitter is divided into a light emitting unit located in the light emitting region and a peripheral portion located in the peripheral region,
at least a portion of the peripheral portion forms an inclined portion,
at least a portion of the inclined portion satisfies a condition 1 or 2 and satisfies a condition 3,
the condition 1 is that a thickness of the lens layer in the peripheral portion is smaller than a thickness of the lens layer in the light emitting unit,
the condition 2 is that formation of the lens layer is avoided, and
the condition 3 is that the thickness of the sealing layer in the peripheral portion is smaller than the thickness of the sealing layer in the light emitting unit, and
a refractive index of the lens layer is larger than a refractive index of the sealing layer.

Furthermore, the present disclosure may be a light emitting device including: (2) a substrate; and
a light emitter including, in order, a light emitting element, a first layer, and a second layer on the substrate,
in which a light emitting region as a region where light generated from the light emitting element is emitted to the outside and a peripheral region as an outer region of the light emitting region are defined,
in a case where a direction along a thickness direction of the light emitter is defined as a line-of-sight direction, and the light emitter is divided into a light emitting unit located in the light emitting region and a peripheral portion located in the peripheral region,
at least a portion of the peripheral portion forms an inclined portion,
at least a portion of the inclined portion satisfies a condition 4 or 5 and satisfies a condition 6,
the condition 4 is that a thickness of the first layer in the peripheral portion is smaller than a thickness of the first layer in the light emitting unit,
the condition 5 is that formation of the first layer is avoided,
the condition 6 is that the thickness of the second layer in the peripheral portion is smaller than the thickness of the second layer in the light emitting unit, and
a refractive index of the first layer is larger than a refractive index of the second layer.

The present disclosure may be, for example, (3) an electronic device including the display device according to (1) described above.

### BRIEF DESCRIPTION OF DRAWINGS

FIG. 1 is a plan view for explaining an example of a display device according to a first embodiment.

FIG. 2 is a cross-sectional view for explaining an example of the display device according to the first embodiment.

FIGS. 3A and 3B are cross-sectional views for explaining a method of manufacturing the display device according to the first embodiment.

FIG. 4 is a cross-sectional view for explaining an example of a display device according to the first embodiment.

FIG. 5 is a cross-sectional view for explaining Modification 1 of the display device according to the first embodiment.

FIG. 6A is a cross-sectional view for explaining Modification 2 of the display device according to the first embodiment.

FIG. 6B is a cross-sectional view for explaining Modification 2 of the display device according to the first embodiment.

FIG. 7 is a plan view for explaining Modification 3 of the display device according to the first embodiment.

FIG. 8 is a cross-sectional view for explaining an example of a display device according to a second embodiment.

FIG. 9 is a cross-sectional view for explaining an example of a display device according to a third embodiment.

FIG. 10 is a cross-sectional view for explaining an example of a display device according to the third embodiment.

FIG. 11 is a cross-sectional view for explaining a modification of the display device according to the third embodiment.

FIGS. 12A and 12B are diagrams for explaining an example of an electronic device using a display device.

FIG. 13 is a diagram for explaining an example of the electronic device using the display device.

FIG. 14 is a diagram for explaining an example of the electronic device using the display device.

### MODE FOR CARRYING OUT THE INVENTION

Hereinafter, an implementation example and the like according to the present disclosure will be described with reference to the drawings. Note that, the description will be made in the following order. In the present specification and the drawings, configurations having substantially the same functional configuration are denoted by the same reference signs, and redundant descriptions are omitted.

Note that, the description will be given in the following order.
1. First Embodiment
2. Second Embodiment
3. Third Embodiment
4. Fourth Embodiment
5. Fifth Embodiment
6. Electronic device
7. Illumination device

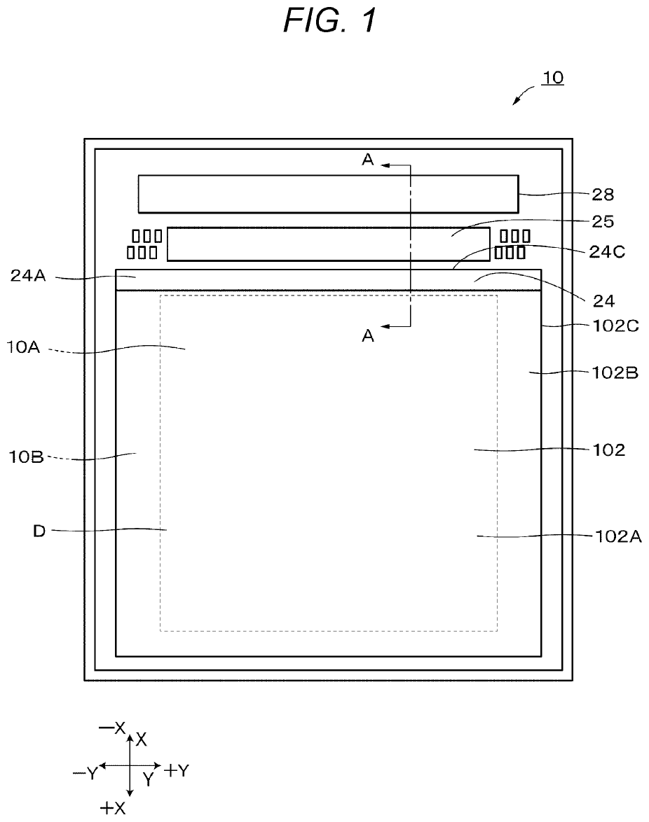

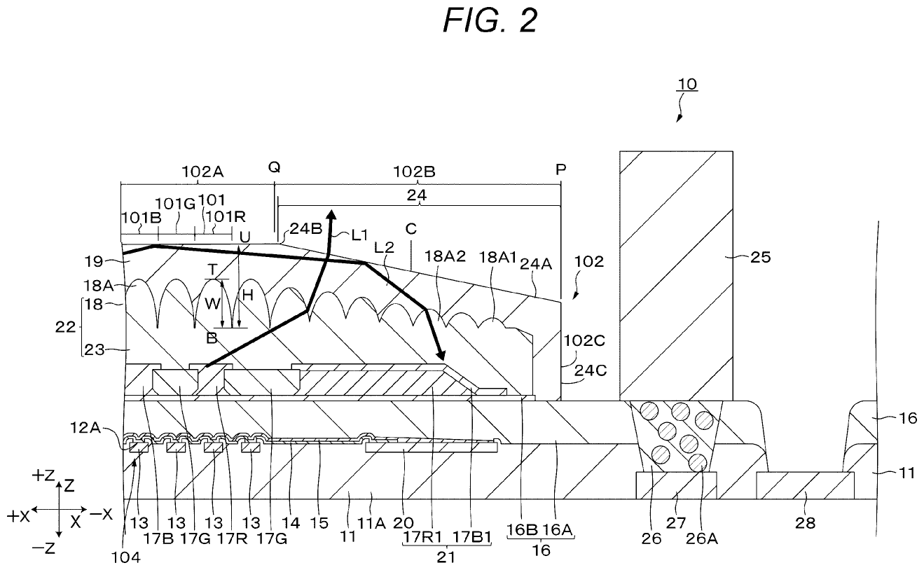

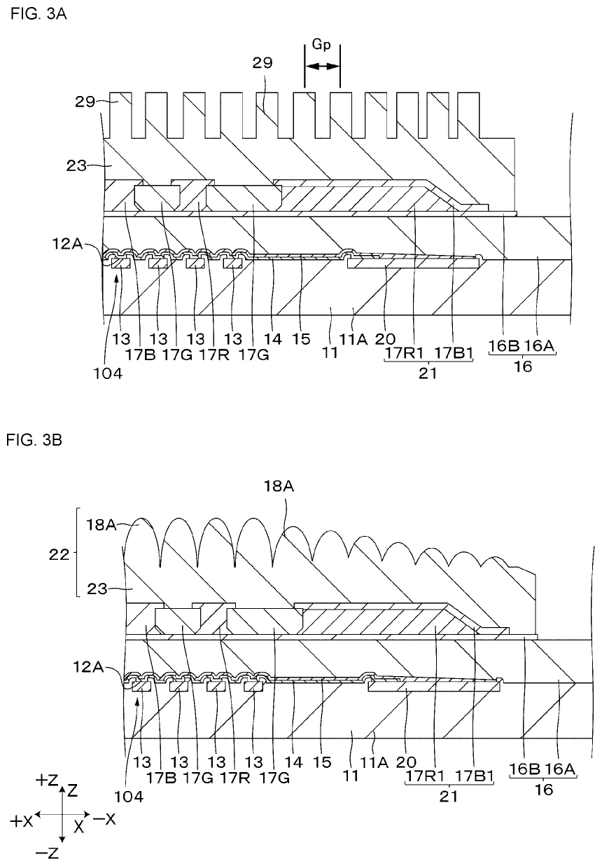

The following description is preferred specific examples of the present disclosure, and the content of the present disclosure is not limited to these embodiments and the like. Furthermore, in the following description, directions of front and back, left and right, up and down, and the like are indicated in consideration of convenience of description, but the content of the present disclosure is not limited to these directions. In examples of FIGS. 1 and 2, it is assumed that the Z-axis direction is the up and down direction (upper side is in a +Z direction, and lower side is in a −Z direction), the X-axis direction is the front and back direction (front side is in a +X direction, and back side is in a −X direction), and the Y-axis direction is the left and right direction (right side is in a +Y direction, and left side is in a −Y direction), and the description will be made on the basis of this. This similarly applies to FIGS. 3 to 11. A relative magnitude ratio of the size and thickness of each layer illustrated in each drawing of FIG. 1 and the like is described for convenience, and do not limit actual magnitude ratios. This similarly applies to each drawing of FIGS. 2 to 11 regarding the definition and the magnitude ratio regarding these directions.

Examples of the light emitting device according to the present disclosure include a display device and an illumination device. In the following first to fifth embodiments, a case where the light emitting device is a display device will be described.

### 1 First Embodiment

### 1-1 Configuration of Display Device

An organic electroluminescence (EL) display device 10 (OLED) (hereinafter, simply referred to as the “display device 10”) as an example of a display device according to an embodiment of the present disclosure will be described below with reference to FIGS. 1 and 2. FIG. 1 is a plan view illustrating an example of a configuration of the display device 10. FIG. 2 is a cross-sectional view for explaining a state of a longitudinal cross section taken along line A-A in FIG. 1. As illustrated in FIG. 2, the display device 10 includes a drive substrate 11 and a light emitter 102 provided on the drive substrate 11.

### (Light Emitting Region and Peripheral Region)

In the display device 10, a light emitting region 10A and a peripheral region 10B are defined on a display surface D side. The light emitting region 10A is defined as a region where light generated from a plurality of light emitting elements 104 of a light emitter 102 is emitted to the outside, and is a display region. The peripheral region 10B is defined as an outer region of the light emitting region 10A. In the example of FIG. 1, the light emitting region 10A is formed as a rectangular region, and a region defined as a rectangular annular region outside the light emitting region 10A is the peripheral region 10B. A position of an outer edge of the light emitting region 10A is a position of an inner peripheral edge of the peripheral region 10B, and the light emitting region 10A and the peripheral region 10B are in contact with each other at a boundary. The display surface D indicates a surface on which light generated from the light emitting element 104 is extracted to the outside in the display device 10.

Hereinafter, a case where the display device 10 is a top emission type display device will be described as an example. The top emission type indicates a method in which a light emitting element is disposed on a display surface side relative to a drive substrate. Therefore, in the display device 10, the drive substrate 11 is located on a back surface side of the display device 10, and a direction (+Z direction) from the drive substrate 11 toward a light emitting element 104 described later is a front surface side (display surface side in a display region as a light emitting region 10A, upper surface side) direction of the display device 10. In the display device 10, light generated from the light emitting element 104 is directed in the +Z direction and emitted to the outside. In the following description, in each layer constituting the display device 10, a surface on the display surface side in the display region (light emitting region 10A) of the display device 10 is referred to as a first surface (upper surface), and a surface on the back surface side of the display device 10 is referred to as a second surface (lower surface). Note that this does not prohibit a case where the display device 10 according to the present disclosure is a bottom emission type display device. The display device 10 is also applicable to a bottom emission type display device. In the bottom emission type, light generated from the light emitting element 104 is directed in the −Z direction and emitted to the outside.

### (Configuration of Sub-Pixel)

In the example of the display device 10 illustrated in FIG. 1, one pixel includes a combination of a plurality of sub-pixels corresponding to a plurality of color types. In this example, three colors of red, green, and blue are determined as the plurality of color types, and three types of a sub-pixel 101R, a sub-pixel 101G, and a sub-pixel 101B are provided as the sub-pixels. The sub-pixel 101R, the sub-pixel 101G, and the sub-pixel 101B are a red sub-pixel, a green sub-pixel, and a blue sub-pixel, respectively, and display red, green, and blue, respectively. However, the example of FIG. 1 is an example, and the color types of the plurality of sub-pixels are not limited. Furthermore, wavelengths of light corresponding to respective color types of red, green, and blue can be determined as, for example, wavelengths in a range of 610 nm to 650 nm, a range of 510 nm to 590 nm, and a range of 440 nm to 480 nm, respectively. Furthermore, examples of layouts of the individual sub-pixels 101R, 101G, and 101B include a layout in which combinations of sub-pixels 101 formed in a stripe shape are arranged in a matrix. In the example of FIG. 1, the sub-pixels 101R, 101G, and 101B are two-dimensionally provided in the light emitting region 10A.

In the following description, in a case where the sub-pixels 101R, 101G, and 101B are not particularly distinguished, a word referred to the sub-pixel 101 is used.

### (Drive Substrate)

The drive substrate 11 is provided with various circuits for driving the plurality of light emitting elements 104 on a substrate 11A. Examples of the various circuits include a drive circuit that controls driving of the light emitting elements 104 and a power supply circuit that supplies power to the plurality of light emitting elements 104 (none of which are illustrated).

The substrate 11A may include, for example, glass or resin having low moisture and oxygen permeability, or may include a semiconductor in which a transistor or the like is easily formed. Specifically, the substrate 11A may be a glass substrate, a semiconductor substrate, a resin substrate, or the like. The glass substrate includes, for example, high strain point glass, soda glass, borosilicate glass, forsterite, lead glass, quartz glass, or the like. The semiconductor substrate includes, for example, amorphous silicon, polycrystalline silicon, monocrystalline silicon, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

A plurality of contact plugs (not illustrated) for connecting the light emitting elements 104 to the various circuits provided on the substrate 11A is provided on the first surface of the drive substrate 11.

### (Light Emitter)

As illustrated in FIG. 2, the display device 10 includes the light emitter 102 on the drive substrate 11. The light emitter 102 includes the light emitting element 104, a first layer, and a second layer in this order from the drive substrate 11 side. In the example of FIG. 2, the light emitter 102 includes a plurality of the light emitting elements 104. Furthermore, the first layer is formed so as to cover the light emitting element 104, and the second layer is formed so as to cover the first layer. The first layer and the second layer are not particularly limited as long as they are layers having a function of protecting the light emitting element 104; however, in the display device 10 according to the first embodiment, as illustrated in FIG. 2, a case where the first layer is the lens layer 18 and the second layer is the sealing layer 19 is taken as an example. Note that this similarly applies to the second to fifth embodiments.

### (Light Emitting Element)

In the display device 10, the plurality of light emitting elements 104 is provided on the first surface of the drive substrate 11. In the example of FIG. 2 and the like, the light emitting element 104 is an organic electroluminescence element (organic EL element). Furthermore, in this example, as the plurality of light emitting elements 104, light emitting elements in which red, green, and blue light are light emitted from the respective light emitting surfaces are provided so as to correspond to the respective sub-pixels 101R, 101G, and 101B. The plurality of light emitting elements 104 is, for example, two-dimensionally arranged in a prescribed arrangement pattern such as a matrix shape or the like.

Each of the light emitting elements 104 includes a first electrode 13, an organic layer 14, and a second electrode 15. The first electrode 13, the organic layer 14, and the second electrode 15 are stacked in this order from the drive substrate 11 side in a direction from the second surface toward the first surface.

### (First Electrode)

A plurality of the first electrodes 13 is provided on the first surface side of the drive substrate 11. The first electrodes 13 are electrically separated from each other for the respective sub-pixels 101 by an insulating layer described later. The first electrode 13 is an anode electrode. In the example of FIG. 2, the first electrode 13 also functions as a reflective layer. In this case, the first electrode 13 preferably has as high a reflectance as possible. Moreover, the first electrode 13 preferably includes a material having a large work function to enhance luminous efficiency.

The first electrode 13 includes at least one of a metal layer or a metal oxide layer. The first electrode 13 may include a single layer film of a metal layer or a metal oxide layer, or a laminated film of a metal layer and a metal oxide layer.

The first electrode 13 may include a reflector and a transparent conductive layer. This can be implemented, for example, by forming the first electrode 13 using a metal layer having light reflectivity as the reflector and a metal oxide film having optical transparency as the transparent conductive layer. Furthermore, the first electrode 13 may be formed with a transparent conductive layer, and the reflector may be provided separately from the first electrode 13.

The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

The metal oxide layer includes, for example, at least one of a mixture of indium oxide and tin oxide (ITO), a mixture of indium oxide and zinc oxide (IZO), or titanium oxide (TiO).

### (Insulating Layer)

In the display device 10, the insulating layer is preferably provided on the first surface side of the drive substrate 11. The insulating layer is provided between the adjacent first electrodes 13, and electrically separates the first electrodes 13 from each other for the respective light emitting elements 104 (that is, for the respective sub-pixels 101). Furthermore, the insulating layer includes a plurality of openings 12A, and the first surfaces of the first electrodes 13 (surfaces facing the second electrode 15) are exposed from the openings 12A. Note that, in the example of FIG. 1 and the like, the insulating layer covers regions from peripheral edge portions to side surfaces (end surfaces) of the first surfaces of the separated first electrodes 13. Then, in this case, the openings 12A are arranged on the first surfaces of the respective first electrodes 13. At this time, the first electrodes 13 are exposed from the openings 12A, and these exposed regions define light emitting regions of the individual light emitting elements 104. In the present specification, a peripheral edge portion of the first surface of the first electrode 13 refers to a region having a predetermined width from an outer peripheral edge on the first surface side of the individual first electrodes 13 toward the inside of the first surface. Note that in FIG. 2, for convenience of description, the insulating layer and the drive substrate 11 are not divided, and the insulating layer is also integrally displayed on the drive substrate 11. This similarly applies to FIGS. 3 to 13.

The insulating layer includes, for example, an organic material or an inorganic material. The organic material includes, for example, at least one of polyimide or acrylic resin. The inorganic material includes, for example, at least one of silicon oxide, silicon nitride, silicon oxynitride, or aluminum oxide.

### (Organic Layer)

The organic layer 14 is provided between the first electrode 13 and the second electrode 15. The organic layer 14 is provided as a layer common to the sub-pixels 101. In the example of FIG. 2, the organic layer 14 is common to the sub-pixels 101R, 101G, and 101B, and is configured to be able to emit white light. However, this does not prohibit an emission color of the organic layer 14 from being other than white, and colors including red, blue, green, and the like may be adopted. That is, the emission color of the organic layer 14 may be, for example, any one of white, red, blue, or green.

The organic layer 14 has, for example, a configuration in which a hole injection layer, a hole transport layer, a light emitting layer, and an electron transport layer are stacked in this order from the first electrodes 13 toward the second electrode 15. An electron injection layer may be provided between the electron transport layer and the second electrode 15. The electron injection layer is for increasing electron injection efficiency. Note that the configuration of the organic layer 14 is not limited thereto, and layers other than the light emitting layer are provided as necessary.

The hole injection layer is a buffer layer for enhancing hole injection efficiency into the light emitting layer and reducing leakage. The hole transport layer is for enhancing hole transport efficiency to the light emitting layer. The electron transport layer is for enhancing electron transport efficiency to the light emitting layer.

The light emitting layer generates light by electrons and holes being combined by an electric field being applied. The light emitting layer is an organic light emitting layer including an organic light emitting material.

### (Second Electrode)

In the light emitting element 104, the second electrode 15 is provided to face the first electrode 13. The second electrode 15 is provided as an electrode common to the plurality of sub-pixels 101. The second electrode 15 is a cathode electrode. The second electrode 15 is preferably a transparent electrode having transparency to light generated in the organic layer 14. The transparent electrode herein includes a transparent electrode including the transparent conductive layer and a transparent electrode including a laminated structure including the transparent conductive layer and a semi-transmissive reflective layer.

As the transparent conductive layer, a transparent conductive material having good optical transparency and a small work function is suitably used. The transparent conductive layer can include, for example, a metal oxide. Specifically, examples of a material of the transparent conductive layer can include a material including at least one of a mixture of indium oxide and tin oxide (ITO), a mixture of indium oxide and zinc oxide (IZO), or zinc oxide (ZnO).

The semi-transmissive reflective layer can include, for example, a metal layer. Specifically, examples of a material of the semi-transmissive reflective layer can include a material including at least one metal element selected from a group including magnesium (Mg), aluminum (Al), silver (Ag), gold (Au), and copper (Cu). The metal layer may include the at least one metal element described above as a constituent element of an alloy. Specific examples of the alloy include an MgAg alloy, an AgPdCu alloy, and the like.

### (Auxiliary Electrode)

In the display device 10, an auxiliary electrode 20 is provided in the peripheral region 10B. The auxiliary electrode 20 relays electrical connection between various circuits formed on the drive substrate 11 side and the second electrode 15. The material of the auxiliary electrode 20 is not particularly limited as long as it is a conductive material, and for example, metal or the like can be used. As illustrated in FIG. 2, the second electrode 15 is extended from the light emitting region 10A to the outside (peripheral region 10B) and connected to the auxiliary electrode 20, so that electrical connection between the second electrode 15 and the auxiliary electrode 20 can be achieved.

### (Element Protective Layer)

An element protective layer 16 is formed on the first surface of the second electrode 15. The element protective layer 16 shields the light emitting element 104 from the outside air, and suppresses moisture ingress into the light emitting element 104 from the external environment. Furthermore, in a case where the semi-transmissive reflective layer of the second electrode 15 includes a metal layer, the element protective layer 16 may have a function of suppressing oxidation of the metal layer.

The element protective layer 16 includes an insulating material. As the insulating material, for example, thermosetting resin or the like can be used. In addition, the insulating material may be SiO, SiON, AlO, TiO, or the like. In this case, as the element protective layer 16, a CVD film containing SiO, SiON, or the like, an ALD film containing AlO, TiO, SiO, or the like, or the like can be exemplified. The element protective layer 16 may be formed as a single layer, or may be formed in a state where a plurality of layers is stacked. In the example of FIG. 2, the element protective layer 16 is formed in a state where a first layer 16A and a second layer 16B are stacked. The first layer 16A can exemplify a CVD film. The second layer 16B can exemplify an ALD film. Note that the CVD film indicates a film formed using chemical vapor deposition. The ALD film indicates a film formed using atomic layer deposition.

### (Color Filter)

In the display device 10 illustrated in FIG. 2, a color filter 17 is provided on the first surface side (upper side, +Z direction side) of the element protective layer 16. As the color filter 17, an on-chip color filter (OCCF) can be exemplified. The color filter 17 is provided according to the color type of the sub-pixel 101. Examples of the color filters 17 include a red color filter (red filter 17R), a green color filter (green filter 17G), and a blue color filter (blue filter 17B) in the example of FIG. 2. The red filter 17R, the green filter 17G, and the blue filter 17B are provided in the sub-pixels 101R, 101G, and 101B, respectively. Since the color filter 17 is provided in the display device 10, light corresponding to the color type of the sub-pixels 101R, 101G, and 101B can be effectively extracted to the outside.

Note that in FIG. 2, the color filter 17 is provided with a red color filter (red filter 17R1) as a light shielding filter and a blue color filter (blue filter 17B1) as a light shielding filter at a position corresponding to the upper side of the auxiliary electrode 20 in the peripheral region 10B. The red filter 17R1 and the blue filter 17B1 are stacked to form a light shielding layer 21 described later. Note that the green filter 17G adjacent to the light shielding layer 21 is the color filter 17 formed from the sub-pixel 101 located on an outermost side of the light emitting region 10A to a predetermined position of the peripheral region 10B, and is formed in a region wider than the other color filters 17 formed in the light emitting region 10A. The color filter 17 formed on the outermost side of the light emitting region 10A is formed in a region wider than the other color filters 17 formed on the inner side of the light emitting region 10A, whereby adhesion of the color filter 17 to the element protective layer 16 is reinforced.

### (Light Shielding Layer)

The light emitter 102 preferably includes a light shielding layer 21 in a peripheral portion 102B described later, which is located in the peripheral region 10B. In the example of FIG. 2, the light shielding layer 21 is formed on an upper side (+Z direction side) of the auxiliary electrode 20. Therefore, it is possible to suppress a phenomenon in which external light entering the inside of the display device 10 from the outside of the display device 10 is reflected by the auxiliary electrode 20. Furthermore, the light shielding layer 21 is preferably formed in an inclined portion 24 described later. In this case, the light reflected at an interface between the inclined portion 24 and the outside easily travels toward the light shielding layer 21.

The light shielding layer 21 is not particularly limited as long as it is a layer capable of suppressing reflection of visible light. As described above using the example of FIG. 2, the light shielding layer 21 preferably has a laminated structure in which the red filter 17R1 and the blue filter 17B1 are stacked. Therefore, when a process of manufacturing the color filter 17 is performed, the light shielding layer 21 can be formed together.

### (Optical Adjustment Layer)

In the display device 10, an optical adjustment layer 22 is formed on the color filter 17. The optical adjustment layer 22 has a layer structure having a light condensing function of directing a direction of light traveling in an oblique direction (direction away from the light emitting region 10A) in the color filter 17 from the light emitting element 104 toward the outside toward the light emitting region 10A side (Z-axis direction side). As illustrated in the example of FIG. 2, specifically, a layer structure in which a lens layer 18 as the first layer is formed on a filter protective layer 23 for protecting the color filter 17 can be exemplified as the optical adjustment layer 22. The lens layer 18 is a layer including a plurality of lenses 18A. Hereinafter, in the display device 10 according to the first embodiment, a case where the optical adjustment layer 22 has a layer structure in which the lens layer 18 is provided on the filter protective layer 23 will be described as an example. In this case, the display device 10 is in a state in which the lens layer 18 is provided on the upper side (+Z direction side) of the light emitting element 104. Note that the optical adjustment layer 22 includes the filter protective layer 23 and the lens layer 18 similarly in the second to fifth embodiments.

### (Filter Protective Layer)

A filter protective layer 23 is provided on the color filter 17. The filter protective layer 23 may have a function of a flattening layer that flattens a surface on which the color filter 17 is formed. The material of the filter protective layer 23 is not particularly limited, and for example, may be formed with a similar material to the element protective layer 16 described above, or may be formed with a similar material to the lens layer 18 described later. In a case where the filter protective layer 23 and the lens layer 18 are formed with a similar material, it is easy to make the filter protective layer 23 and the lens layer 18 continuous layers.

### (Lens Layer)

In the example of FIG. 2, the lens layer 18 is formed by the plurality of lenses 18A provided on the first surface side (upper side, +Z direction side) of the filter protective layer 23. The lens 18A is preferably an on-chip lends (OCL). The lens 18A is provided in a portion corresponding to a predetermined region including at least the light emitting region 10A. In the example of FIG. 2, the lens 18A is provided in a portion of the light emitter 102 corresponding to both a light emitting unit 102A and the peripheral portion 102B, so that the lens layer 18 is formed in both the light emitting unit 102A and the peripheral portion 102B.

In the example of FIG. 2, each lens 18A forming the lens layer 18 is formed in a convex shape having a curved surface convexly curved in a direction away from the drive substrate 11, and is a so-called convex lens. That is, the lens layer 18 includes a plurality of convex lenses. The lens 18A is preferably disposed at a position corresponding to each of the sub-pixels 101. In this case, it is easy to perform adjustment so that the light generated from the light emitter 102 provided in each of the sub-pixels 101 is emitted from the region of each of the sub-pixels 101. The display device 10 includes the lens 18A, whereby light extraction efficiency can be improved.

### (Thickness of Adjacent Lens)

In the example of FIG. 2, regarding the thickness of the lens 18A, in the inclined portion 24 described later, a thickness W of the lens 18A (distance from a proximal end B to a distal end T of the lens 18A) in the lens 18A1 at a position close to an outer peripheral edge P of the peripheral portion 102B is smaller than the thickness W in the lens 18A2 at a position far from the outer peripheral edge P of the peripheral portion 102B. In this case, in the display device 10, in the peripheral portion 102B, the plurality of lenses 18A is formed such that the thickness W becomes smaller as the lens 18A is closer to the outer peripheral edge P. Furthermore, in the peripheral portion 102B, a light shielding layer 21 is formed at a position of the drive substrate 11 side (lower side, −Z direction side as the second surface side) relative to the lens 18A. In the display device 10, since the lens 18A and the light shielding layer 21 are formed in the peripheral portion 102B in this manner, in a case where the light L2 reflected at an interface (air interface) on the surface side of the sealing layer 19 among laterally propagated light is directed in a lens direction, it becomes easy to guide the light L2 from the lens 18A to the light shielding layer 21. The laterally propagated light indicates light that has been propagated in a direction crossing a direction along a thickness direction of the light emitter 102. Note that for the lens 18A disposed in the light emitting unit 102A, the thickness of the lens 18A is preferably approximately constant.

### (Sealing Layer)

In the display device 10, the sealing layer 19 is formed so as to cover the lens layer 18. The sealing layer 19 seals the light emitting element 104 and the lens layer 18. Note that in the example of FIG. 2, sealing of the color filter 17 is also reinforced by the sealing layer 19.

The material of the sealing layer 19 is not particularly limited, and examples thereof include resins such as an ultraviolet curable resin and a thermosetting resin.

### (Inclined Portion)

In the display device 10, in a case where the light emitter 102 is divided into the light emitting unit 102A located in the light emitting region 10A and the peripheral portion 102B located in the peripheral region 10B with the direction (Z-axis direction) along the thickness direction of the light emitter 102 as the line-of-sight direction, the inclined portion 24 is formed in at least a portion of the peripheral portion 102B. In the example illustrated in FIGS. 1 and 2, the inclined portion 24 is formed in a portion including at least a portion of the outer peripheral edge P of the peripheral portion 102B in the peripheral portion 102B. The inclined portion 24 is a portion formed by dividing a portion included in a predetermined region from the light emitter 102 with the direction along the thickness direction of the light emitter 102 as the line-of-sight direction, and is defined as a portion that forms the inclined surface 24A on the surface side (first surface side) of the light emitter 102. Note that, in the example of FIG. 1, the light emitting unit 102A is formed in a rectangular shape in plan view, and the peripheral portion 102B is formed in a frame shape (rectangular ring shape) in plan view. Then, in this example, the inclined portion 24 is formed along one side of the outer peripheral edge P of the peripheral portion 102B.

In the display device 10 according to the first embodiment, at least a portion of the inclined portion 24 satisfies the following conditions 7 and 8. In the inclined portion 24, the condition 8 is only required to be satisfied at least for a portion forming a laminated structure of the lens layer 18 and the sealing layer 19 in the sealing layer 19. Since the inclined portion 24 is formed in the peripheral portion 102B and satisfies the conditions 7 and 8, it is possible to reduce the amount of light that laterally propagates through the sealing layer 19 and is emitted from an end portion 102C (side end) on the outer peripheral edge P side of the light emitter 102.

Condition 7: The thickness of the lens layer 18 (first layer) in the peripheral portion 102B is smaller than the thickness of the lens layer 18 in the light emitting unit 102A.

Condition 8: The thickness of the sealing layer 19 (second layer) in the peripheral portion 102B is smaller than the thickness of the sealing layer 19 in the light emitting unit 102A.

However, in the condition 7, the thickness of the first layer indicates a distance from a bottom surface to an upper surface of the first layer, and in a case where the first layer is the lens layer 18, the thickness W of the lens layer 18 is defined to indicate a distance from the proximal end B to the distal end T of the lens 18A forming the lens layer 18 (dimension in the vertical direction (Z-axis direction) of the lens).

In the condition 8, the thickness of the second layer indicates a distance from a bottom surface to an upper surface of the second layer, and in a case where the second layer is the sealing layer 19, the thickness H of the sealing layer 19 is defined to indicate a distance from a position of a portion of the sealing layer 19 in contact with the proximal end B of the lens 18A to a surface U of the sealing layer 19 (dimension of the sealing layer 19 in the vertical direction (Z-axis direction)).

### (Range of Inclined Portion)

For a formation range of the inclined portion 24, the inclined portion 24 is only required to be formed in the peripheral portion 102B, and is preferably formed at least in a portion from a center C to the outer peripheral edge P of the peripheral portion 102B. In this case, a proximal end 24B of the inclined portion 24 is positioned between an inner peripheral edge Q of the peripheral portion 102B and the center C. The formation range of the inclined portion 24 can be determined in consideration of conditions such as the thickness of the light emitter 102, the sizes of the inclined portion 24 and a structure (for example, an integrated circuit board 25 or the like) disposed outside the light emitter 102, and a separation distance F.

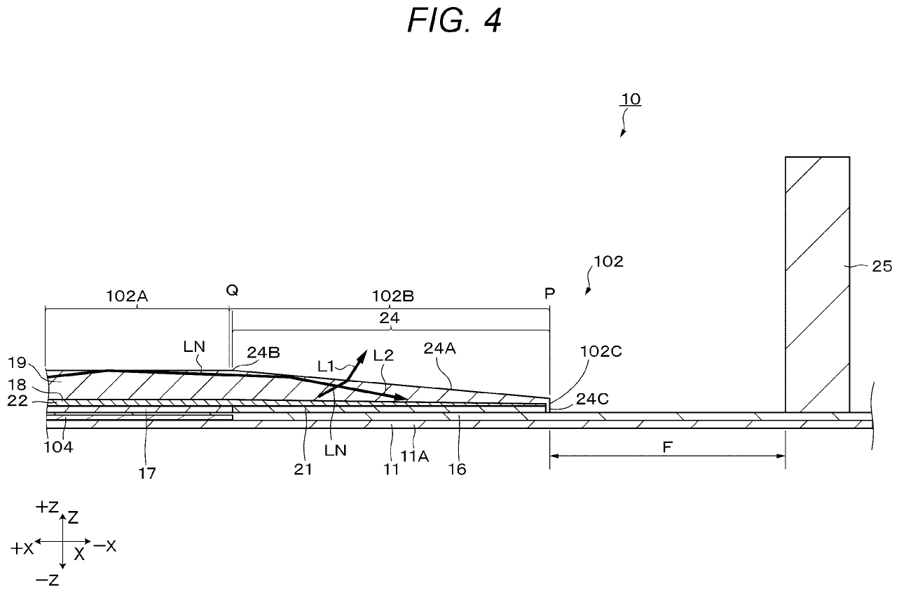

In the display device 10, since the inclined portion 24 is formed in a predetermined range, as illustrated in FIGS. 2 and 4, the light propagating laterally in the light emitter 102 in a wider range can be light L1 refracted in a direction away from the end portion 102C by the inclined portion 24, and the light propagating laterally can be efficiently suppressed from being emitted from the position of the outer peripheral edge P of the peripheral portion 102B. Furthermore, it is easy to obtain the light L2 in which a part of the light propagating laterally in the sealing layer 19 is reflected by the inclined portion 24 and directed toward the lens 18A, and, in addition, it is easy to form a state of being directed to the light shielding layer 21. Note that the center C of the peripheral portion 102B described herein indicates an intermediate position between the outer peripheral edge P and the inner peripheral edge Q of the peripheral portion 102B in a case where a direction from the center of the light emitter 102 toward the outside is defined as an inward and outward direction with the direction along the thickness direction of the light emitter 102 as the line-of-sight direction. FIG. 4 is a cross-sectional view for explaining the function and effect of the display device 10 according to the first embodiment. However, in FIG. 4, for convenience, the layer configurations of the lens 18A and the light emitting element 104 are omitted, and the description of covering an end surface of the light shielding layer 21 with the optical adjustment layer 22 is omitted.

As illustrated in FIGS. 2 and 4, the inclined portion 24 is formed outside the light emitting unit 102A (formation of the inclined portion 24 is avoided in the light emitting unit 102A). Since the inclined portion 24 is avoided from being formed in the light emitting unit 102A, occurrence of thickness unevenness in the light emitting unit 102A is reduced.

### (Surface Shape of Inclined Portion)

In the examples of FIGS. 2 and 4, the surface (first surface) of the inclined portion 24 has an inclined surface 24A inclined downward toward the outer peripheral edge P of the peripheral portion 102B. In this case, a surface of the sealing layer 19 is an inclined surface inclined downward toward the outside at a portion of the inclined portion 24.

The inclined surface 24A forming the surface of the inclined portion 24 may be a non-curved inclined surface (curved plane) or a curved inclined surface inclined downward toward the outer peripheral edge P of the peripheral portion 102B. In a case where the inclined surface 24A is a curved inclined surface, the inclined surface 24A may be a convex curved surface or a concave curved surface.

Furthermore, a plurality of concavoconvexs may be formed on the inclined surface 24A. For example, in a case where the shape of the lens 18A formed on the lower side (−Z direction side) of the sealing layer 19 is reflected on the surface of the sealing layer 19, a plurality of concavoconvexs according to layout of the lens 18A is formed on the inclined surface 24A.

### (Refractive Index)

In the display device 10, the refractive index of the lens layer 18 as the first layer is larger than the refractive index of the sealing layer 19 as the second layer. In a case where the refractive index of the lens layer 18 is larger than the refractive index of the sealing layer 19, the lens layer 18 is a high refractive index layer, and the sealing layer 19 is a low refractive index layer; therefore, for example, even when the light generated from the light emitting element 104 travels slightly obliquely, the light is refracted toward the Z-axis direction at an interface between the lens 18A and the sealing layer 19 when passing through the lens 18A (when traveling from the high refractive index layer to the low refractive index layer). Therefore, since the refractive index of the lens layer 18 is larger than the refractive index of the sealing layer 19, the light condensing function by the lens layer 18 can be enhanced.

From the viewpoint of enhancing the light condensing function by the lens layer 18, the refractive index of the lens layer 18 is preferably in a range of about 1.55 or more and 1.7 or less. Furthermore, from the same viewpoint, the refractive index of the sealing layer 19 is preferably in a range of about 1.2 or more and 1.45 or less. As an example of such a combination of the refractive index values of the lens layer 18 and the sealing layer 19, a combination of 1.58 and 1.38 can be exemplified.

### (Integrated Circuit Board)

In the display device 10, various structures are provided around the light emitter 102. For example, as illustrated in FIGS. 1 and 2, in the display device 10, an integrated circuit board 25 that controls display of the display device 10 is provided as a structure. The integrated circuit board 25 includes, for example, a display driver integrated circuit (DDIC) that controls a light emission state of the light emitting unit 102A. In the display device 10 according to the first embodiment, the integrated circuit board 25 is provided at a position facing an outer end portion 24C of the inclined portion 24 in the end portion 102C on the outer peripheral edge P side of the peripheral portion 102B.

The circuit of the integrated circuit board 25 is electrically connected to the circuit of the drive substrate 11. A method of connecting the circuit on the drive substrate 11 side and the circuit of the integrated circuit board 25 is not particularly limited. Examples of the connection method include, as shown in FIG. 2, a method of using an anisotropic conductive film (ACF) (ACF 26 in FIG. 2) including a resin film containing conductive particles 26A. This method can be implemented, for example, as follows. A connection terminal 27 connected to the circuit on the drive substrate 11 side is positioned so as to face the integrated circuit board 25 via the ACF 26. By pressure-bonding the integrated circuit board 25, the ACF 26, and the connection terminal, the circuit of the drive substrate 11 and the circuit of the integrated circuit board 25 are electrically connected via the conductive particles 26A included in the ACF 26. Note that in FIG. 2, reference numeral 28 is a pad for electrically connecting the drive substrate 11 to a flexible printed circuit board (FPC) (not illustrated).

### 1-2. Method of Manufacturing Display Device

Next, an example of a method of manufacturing the display device 10 according to the first embodiment will be described in detail with reference to FIG. 3 using a case where the display device 10 of FIGS. 1 and 2 is manufactured as an example.

The drive substrate 11 is formed by forming transistors and various wiring lines on the substrate 11A including a semiconductor material such as silicon.

The light emitting element 104 is formed on the drive substrate 11. The light emitting element 104 can be formed by providing the first electrode 13, the organic layer 14, and the second electrode 15 on the drive substrate 11. The first electrode 13, the organic layer 14, and the second electrode 15 can be formed by using a technique such as sputtering, lithography, etching, or vapor deposition as necessary.

The element protective layer 16 is formed to cover the second electrode 15. The formation of the element protective layer 16 can be specifically implemented, for example, by forming a material such as SiN on the entire surface by a CVD method.

The color filter 17 is formed on the first surface of the element protective layer 16. The color filter 17 is formed in a shape determined according to the layout of the sub-pixel and the pixel. The color filter 17 can be formed by applying, for example, a photolithography method. The red filter 17R, the green filter 17G, and the blue filter 17B are formed in the layout corresponding to the sub-pixel 101.

The filter protective layer 23 is formed on the first surface of the color filter 17. For example, the filter protective layer 23 can be formed so as to cover the entire first surface of the color filter 17 using a one drop fill (ODF) method.

The lens layer 18 is formed by forming the plurality of lenses 18A on the first surface side of the filter protective layer 23 as follows. First, as illustrated in FIG. 3A, a pattern of a columnar body 29 is formed with an organic resin or the like at a position corresponding to the position of the lens 18A on the filter protective layer 23. At this time, the plurality of columnar bodies 29 is formed such that for an interval (gap Gp) between the adjacent columnar bodies 29 in the peripheral portion, the gap Gp of the columnar body at the position close to the outer peripheral edge P of the light emitter 102 is smaller than the gap Gp of the columnar body at the position far from the outer peripheral edge P (that is, the gap Gp becomes narrower toward the columnar body 29 at the position close to the outer peripheral edge P). Next, a step of giving a thermal history to the plurality of columnar bodies 29 (reflow process) is performed, a part of each of the columnar bodies 29 is dissolved to form the lens 18A, and the lens layer 18 is formed by these lenses 18A. Note that at this time, as the gap between the adjacent columnar bodies 29 is smaller, the adjacent lenses 18A are connected in a narrower space, and the distance (thickness W) from the proximal end B to the distal end T of the lens 18A becomes a small lens (FIG. 3B).

Then, the sealing layer 19 is formed on the first surface side of the lens layer 18. The sealing layer 19 can be formed, for example, by applying and curing an organic resin material on the first surface side of the lens layer 18. Thus, the light emitter 102 is formed on the first surface of the drive substrate 11. Moreover, in addition, various structures are arranged at predetermined positions around the light emitter 102. In this way, the display device 10 is obtained.

### 1-3 Function and Effect

In the display device, in a case where light generated from the light emitting element of the light emitter travels in an oblique direction in the light emitter and is reflected at an interface between the light emitter and an outside to form laterally propagating light, there is a possibility that the laterally propagating light is emitted from an end portion of the light emitter. The laterally propagating light indicates light traveling in a direction crossing the thickness direction of the light emitter among the light generated from the light emitting element.

Furthermore, in the display device, a structure may be disposed around the light emitter. For example, a structure (integrated circuit board or the like) having a height of about 318 μm to 775 μm may be disposed at a position about 2 mm away from the light emitting unit of the light emitter. In such a display device, in a case where the laterally propagating light is emitted from the end portion of the light emitter, there is a possibility that the laterally propagating light is reflected by a structure disposed around the light emitter and becomes stray light. Furthermore, in a case where the structure is an integrated circuit such as DDIC, the structure is irradiated with light emitted from the end portion of the light emitter, which may cause malfunction of the integrated circuit. For this, it is conceivable to form a light shielding film on the structure, and in this case, the manufacturing cost may increase. Thus, in the display device, it has been required to reduce emission of the laterally propagating light from the end portion of the light emitter.

In the display device 10 according to the first embodiment, the inclined portion 24 is formed in the peripheral portion 102B. Therefore, as illustrated in FIG. 4, at the position of the inclined portion 24, the laterally propagating light (light LN) can be the light L1 refracted upward at the interface between the sealing layer 19 and the outside, and the amount of light emitted from the end portion 102C of the light emitter 102 can be reduced. Therefore, even in a case where various structural units such as the integrated circuit board 25 are arranged at positions facing the outer peripheral edge P where the inclined portion 24 is formed, a traveling direction of the light emitted from the light emitter 102 to the outside can be controlled to be directed away from the structural units. Furthermore, in the peripheral portion 102B, in a case where the refractive index of the lens layer 18 is higher than the refractive index of the sealing layer 19, when the laterally propagating light (light LN) is reflected at the interface between the sealing layer 19 and the outside to become reflected light (light L2), the traveling direction of the light L2 can be effectively directed to the lower side (−Z direction side) by the lens 18A. In a case where the light shielding layer 21 is provided at a predetermined position of the peripheral portion 102B, it is easy to form a state in which the light L2 travels toward the light shielding layer 21 through the lens 18A. From this, according to the display device 10 according to the first embodiment, it is possible to reduce emission of the laterally propagating light from the end portion 102C.

Next, a modification of the display device 10 according to the first embodiment will be described.

### 1-4 Variation

### Modification 1

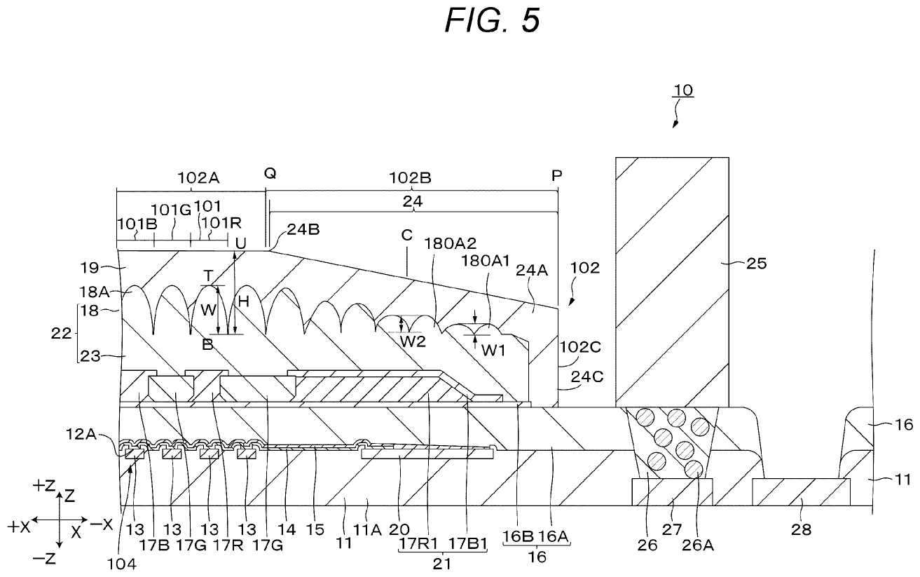

In the lens layer of the display device 10 according to the first embodiment, the thickness W of the lens 18A is smaller as the lens 18A is closer to the outer peripheral edge P in the inclined portion 24; however, the formation pattern of the lens 18A is not limited thereto. In the display device 10 according to the first embodiment, as illustrated in FIG. 5, the plurality of lenses 18A may be provided so that the distance (thickness W) from the proximal end B to the distal end T of the lens 18A decreases gradually (stepwise) toward the outer peripheral edge P of the peripheral portion 102B (Modification 1). FIG. 5 is a cross-sectional view illustrating an embodiment of the display device 10 according to Modification 1.

In the example of FIG. 5, in the peripheral portion 102B, the lens 18A is provided so that the thickness of the lens 18A decreases toward the outer peripheral edge P of the peripheral portion 102B in units of combination of the two adjacent lenses 18A. In FIG. 5, for a pair of two lenses 18A adjacent in the inward and outward direction, in the inclined portion 24, a thickness W1 of the lens 18A in a pair 180A1 of the lenses 18A at the position close to the outer peripheral edge P is smaller than a thickness W2 of the lens 18A in a pair 180A2 of the lenses 18A at the position far from the outer peripheral edge P.

According to the display device 10 according to Modification 1, a degree of freedom in designing the surface shape of the inclined portion 24 can be improved, and it is easy to control refraction of light propagating in the sealing layer 19.

### Modification 2

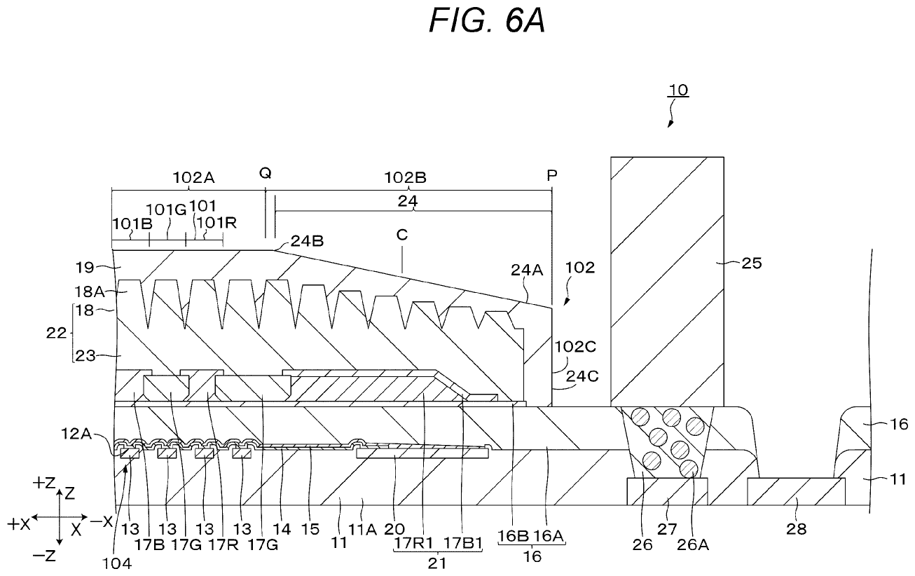

In the display device 10 according to the first embodiment, the shape of the lens 18A is not limited to the example illustrated in FIG. 2. In the display device 10 according to the first embodiment, the lens may have a shape as illustrated in FIGS. 6A and 6B (Modification 2). FIGS. 6A and 6B are cross-sectional views illustrating an embodiment of a display device according to Modification 2.

In the display device 10, as illustrated in FIG. 6A, the lens 18A may be formed in a trapezoidal shape in a longitudinal cross section. Furthermore, as illustrated in FIG. 6B, the lens 18A may be formed in a rectangular shape (so-called box shape) in a longitudinal cross section and a plan view. Note that the longitudinal cross section indicates a cross section along the thickness direction of the light emitter 102 as illustrated in FIGS. 6A and 6B. The plan view indicates a case where the thickness direction of the light emitter 102 is the line-of-sight direction.

### Modification 3

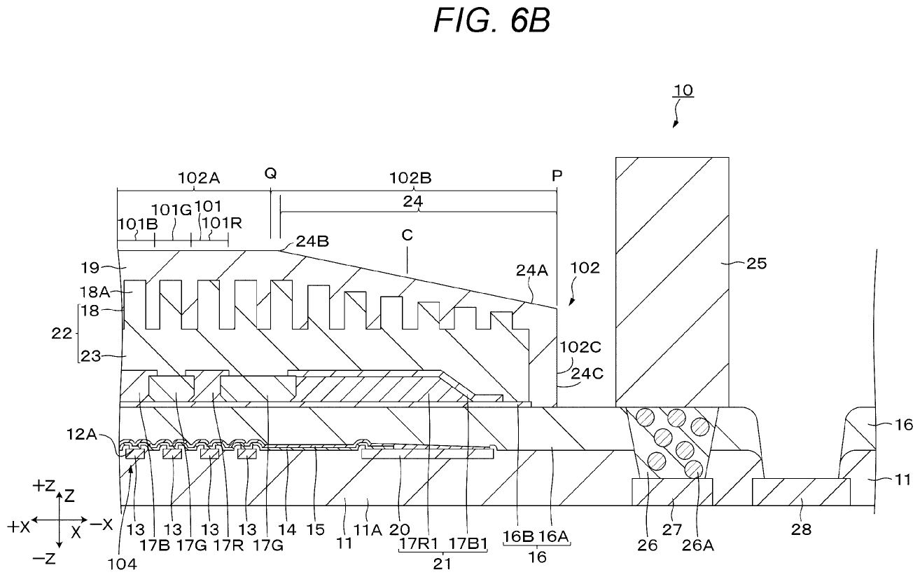

In the display device 10 according to the first embodiment, a portion of the light emitter 102 where the inclined portion 24 is formed is not limited to one side of the outer peripheral edge P of the peripheral portion 102B. As illustrated in FIG. 7, in the display device 10 according to the first embodiment, the inclined portion 24 may be formed on the entire outer peripheral edge P of the peripheral portion 102B (Modification 3). FIG. 7 is a plan view illustrating an embodiment of the display device according to Modification 3. In the example of FIG. 7, the portion where the inclined portion 24 is formed is formed on four sides forming the outer peripheral edge P of the peripheral portion 102B.

According to the display device 10 according to Modification 3, since the inclined portion 24 is formed on the entire outer peripheral edge P of the peripheral portion 102B, it is possible to effectively suppress the laterally propagating light from being laterally outside from the end portion 102C of the light emitter 102 in a wider range.

### 2 Second Embodiment

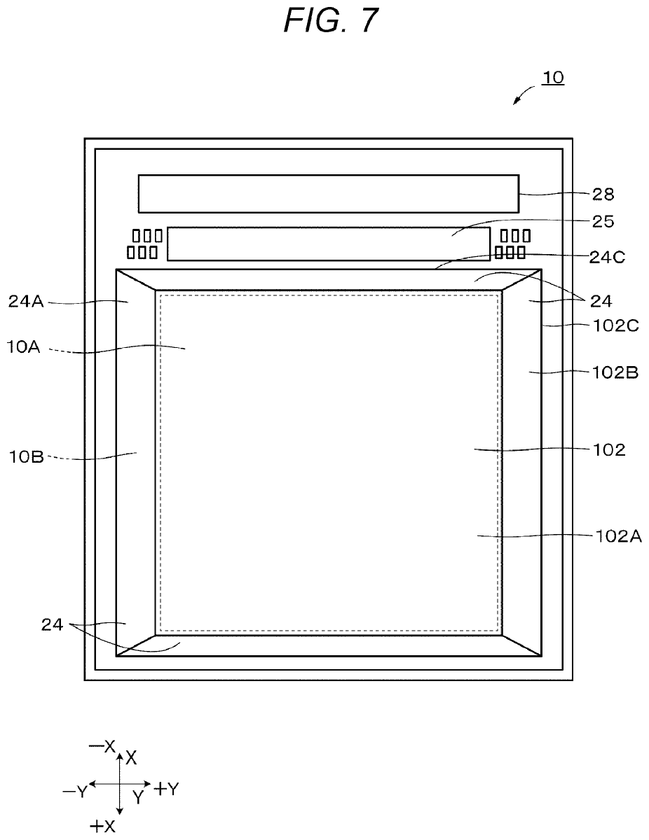

In the display device 10 according to the first embodiment, the lens layer 18 as the first layer is formed in the light emitting unit 102A and the peripheral portion 102B; however, as illustrated in FIG. 8, the lens layer 18 may be omitted in the peripheral portion 102B (second embodiment). FIG. 8 illustrates an embodiment of a display device according to the second embodiment.

In a display device 10 according to the second embodiment, a drive substrate 11, a light emitter 102, and a sealing layer 19 are formed similarly to the display device 10 according to the first embodiment.

### (Inclined Portion)

In the display device 10 according to the second embodiment, a lens layer 18 is provided in a light emitting unit 102A, and the arrangement of the lens layer 18 is avoided in a peripheral portion 102B. In this case, at least a portion of an inclined portion 24 satisfies the following condition 9 instead of the condition 7 described above. In the example of FIG. 8, the entire inclined portion 24 satisfies the following condition 9 instead of the condition 7 described above. Note that the condition 8 described above is similar to that of the display device 10 according to the first embodiment.

Condition 9: Formation of the lens layer 18 is avoided.

According to the display device 10 according to the second embodiment, a degree of freedom in designing the surface shape of the inclined portion 24 can be improved, and it is easy to control refraction of light propagating in the sealing layer 19.

### 3 Third Embodiment

### 3-1 Configuration of Display Device

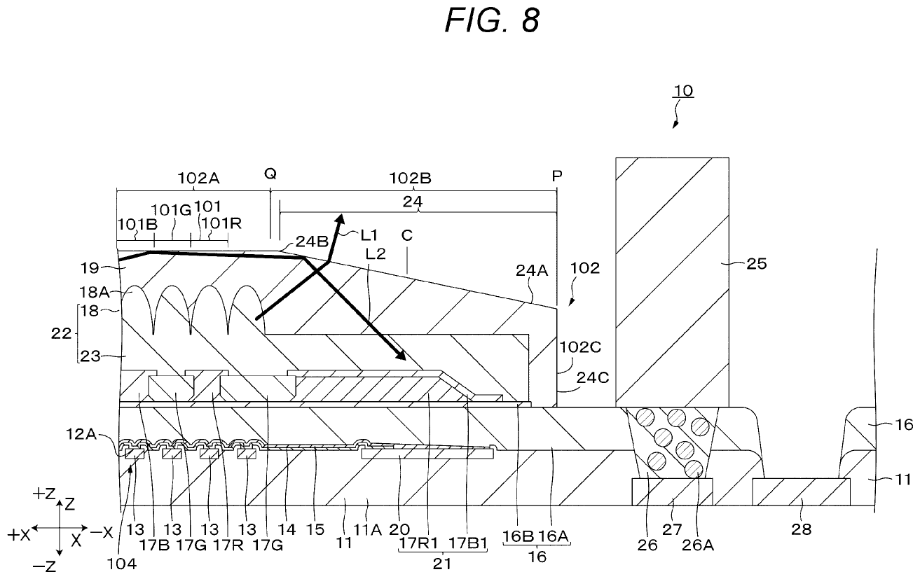

In the display device 10 according to the first embodiment or the second embodiment, as illustrated in FIG. 9, the sealing layer 19 may have a multilayer structure in which a plurality of layers is stacked (third embodiment). FIG. 9 is a cross-sectional view illustrating an example of a display device 10 according to the third embodiment. In the third embodiment, the sealing layer 19 has a multilayer structure in both a light emitting unit 102A and a peripheral portion 102B.

### (Sealing Layer)

In the display device 10 according to the third embodiment, the sealing layer 19 has a multilayer structure having a structure in which a filling resin layer 30 and a counter substrate 31 are stacked in the example of FIG. 9. In a case where the sealing layer 19 has a multilayer structure, a thickness H of the sealing layer 19 in the condition 8 described above indicates a distance from a position of a portion (portion of the filling resin layer 30) of the sealing layer 19 in contact with a proximal end B of the lens 18A to a surface U (surface of the counter substrate 31) of the sealing layer 19.

### (Filling Resin Layer)

In the example of FIG. 9, the filling resin layer 30 is formed on the first surface side of a lens layer 18, is an inner layer disposed inside the counter substrate 31, and seals the lens layer 18 and a light emitting element 104. The filling resin layer 30 can have a function as an adhesive layer for bonding the counter substrate 31 described later to the lens layer 18 side. Examples of the filling resin layer 30 include ultraviolet curable resin, thermosetting resin, and the like.

### (Counter Substrate)

The counter substrate 31 is provided on the filling resin layer 30 in a state of facing the drive substrate 11, and is an outer layer disposed outside the filling resin layer 30. The counter substrate 31 and the filling resin layer 30 are layers adjacent to each other. The counter substrate 31 seals the light emitting element 104 together with the filling resin layer 30. The counter substrate 31 may include a similar material to the substrate 11A included in the drive substrate 11, and preferably includes a material such as resin or glass.

### (Refractive Index of Sealing Layer)

In the sealing layer 19, the refractive index of the filling resin layer 30 (inner layer) is preferably larger than the refractive index of the counter substrate 31 (outer layer). Since such a configuration provided in the display device 10 according to the third embodiment, in a case where light traveling obliquely from the filling resin layer 30 toward the counter substrate 31 is refracted at the interface between the filling resin layer 30 and the counter substrate 31, the traveling direction of the light can be directed further upward (+Z direction side, direction away from the end portion 102C of the light emitter 102).

Furthermore, the refractive index of the lens layer 18 is preferably larger than the refractive index of the sealing layer 19 as described in the first embodiment. Therefore, the refractive index of the lens layer 18 is preferably larger than the refractive index of the filling resin layer 30.

### 3-2 Function and Effect

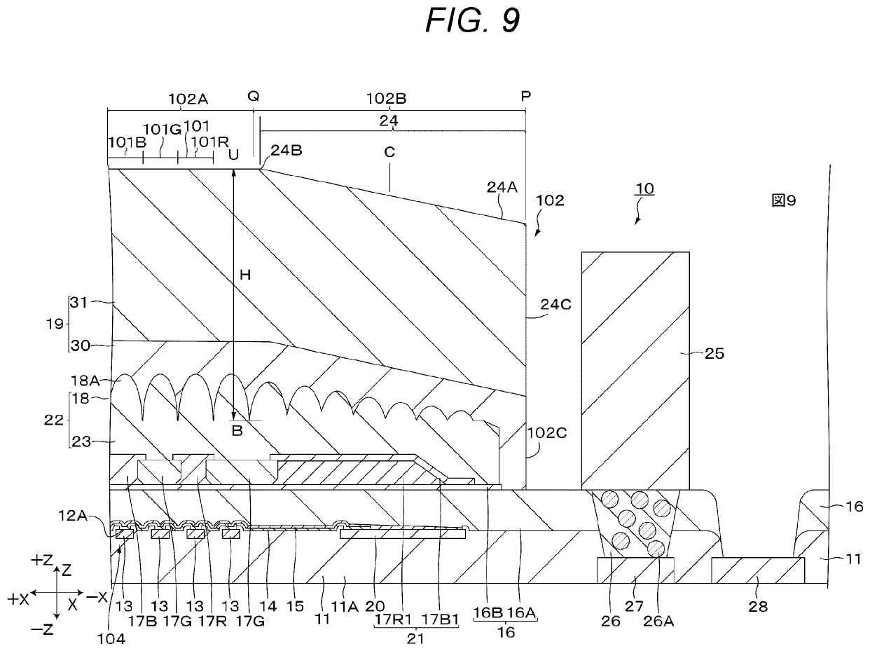

In the display device 10 according to the third embodiment, similarly to the display device 10 according to the first embodiment, as illustrated in FIG. 10, an inclined portion 24 is formed in a peripheral portion 102B. Therefore, at the position of the inclined portion 24, the laterally propagating light (light LN) can be the light L1 refracted upward at the interface between the sealing layer 19 and the outside, and the amount of light emitted from the end portion 102C of the light emitter 102 can be reduced. Therefore, even in a case where a structural unit (for example, the integrated circuit board 25) is disposed at a position facing the outer peripheral edge P of the inclined portion 24, the traveling direction of the light emitted to the outside from the end portion 102C can be controlled to be directed away from the structural unit. Furthermore, in the display device 10 according to the third embodiment, similarly to the display device 10 according to the first embodiment, in the peripheral portion 102B, in a case where the refractive index of the lens layer 18 is higher than the refractive index of the sealing layer 19, when the laterally propagating light (light LN) is reflected at the interface between the sealing layer 19 and the outside to become reflected light (light L2), the traveling direction of the light L2 can be effectively directed to the lower side (−Z direction side) by the lens 18A. Note that FIG. 10 is a cross-sectional view for explaining the function and effect of the display device 10 according to the third embodiment. However, in FIG. 10, for convenience, the layer configurations of the lens 18A and the light emitting element 104 are omitted, and the description of covering an end surface of the light shielding layer 21 with the optical adjustment layer 22 is omitted.

### 3-3 Modifications

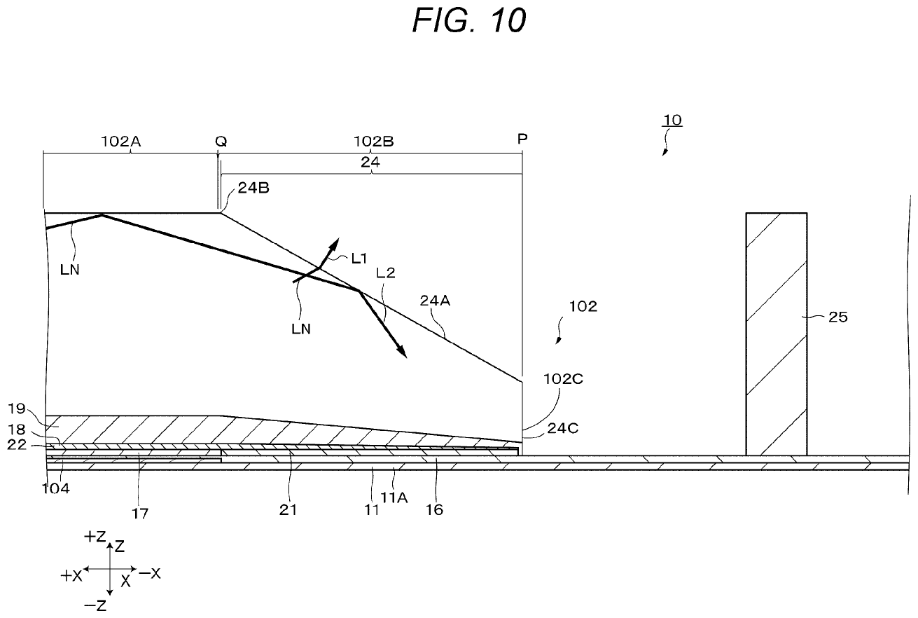

In the display device 10 according to the third embodiment, as illustrated in FIG. 11, regarding the layer structure of the sealing layer 19, the sealing layer 19 in the light emitting unit 102A and the sealing layer 19 in the peripheral portion 102B may be different from each other (modification of the third embodiment). FIG. 11 is a cross-sectional view illustrating an embodiment of the display device 10 according to Modification of the third embodiment. In the example of FIG. 11, the sealing layer 19 has a multilayer structure including the filling resin layer 30 and the counter substrate 31 in the light emitting unit 102A, and has a single layer structure including the counter substrate 31 in the peripheral portion 102B.

As illustrated in FIG. 11, in the modification of the third embodiment, the sealing layer 19 in the inclined portion 24 has a single layer structure. The sealing layer 19 has a multilayer structure at the light emitting unit 102A and has a single layer structure at the inclined portion 24. As a result, it is possible to form a state in which the number of stacked layers is reduced in the inclined portion 24 in the peripheral portion 102B than in the light emitting unit 102A, and it is easy to form the inclined portion 24 in the peripheral portion 102B.

### 4 Fourth Embodiment

In the display device 10 according to the first to third embodiments, the lens 18A forming the lens layer 18 may be a concave lens (not illustrated) (fourth embodiment). Note that in a display device 10 according to the fourth embodiment, the refractive index of the lens layer 18 is preferably smaller than the refractive index of a sealing layer 19. In this case, even when light generated from a light emitting element 104 travels slightly obliquely, the light is easily refracted in the Z-axis direction at a boundary surface between the concave lens and the sealing layer when passing through the concave lens. Note that when the lens 18A is a concave lens in a case where the sealing layer has a multilayer structure as in the third embodiment, the refractive index of the lens layer 18 is preferably smaller than the refractive index of an inner layer (for example, filling resin layer 30) of the sealing layer 19 that is a layer forming an interface with the lens layer 18. Furthermore, in this case, as for the relationship in refractive index between the inner layer and the outer layer (for example, the filling resin layer 30 and the counter substrate 31), as described in the third embodiment, the refractive index of the inner layer is preferably larger than the refractive index of the outer layer (the refractive index of the filling resin layer 30 is larger than the refractive index of the counter substrate 31).

### 5 Fifth Embodiment

The display device 10 according to the first to fourth embodiments is not limited to an organic EL display device. The display device 10 may be a semiconductor light emitting device or the like (not illustrated) (fifth embodiment). The semiconductor light emitting device may be a semiconductor display device such as a liquid crystal on silicon (LCOS) display device or a light emitting diode (LED) display device.

In the display device 10 according to the fifth embodiment, the light emitting element 104 is a semiconductor light emitting element. Other configurations of the display device 10 according to the fifth embodiment may be similar to those of the first embodiment.

The display device 10 according to the fifth embodiment can also obtain the similar effects to the display device 10 of the first to fourth embodiment.

### 6 Application Example

### (Electronic Device)

The light emitting device according to the present disclosure may be provided in various electronic devices. For example, the display device (display device 10) according to the above-described embodiment (any one of the first to fifth embodiments) may be provided in various electronic devices. Especially, the display device according to the above-described embodiment is preferably provided in an electronic viewfinder of a video camera or a single-lens reflex camera, a head mounted display, or the like in which high resolution is required, used for enlarging near the eyes.

### Specific Example 1

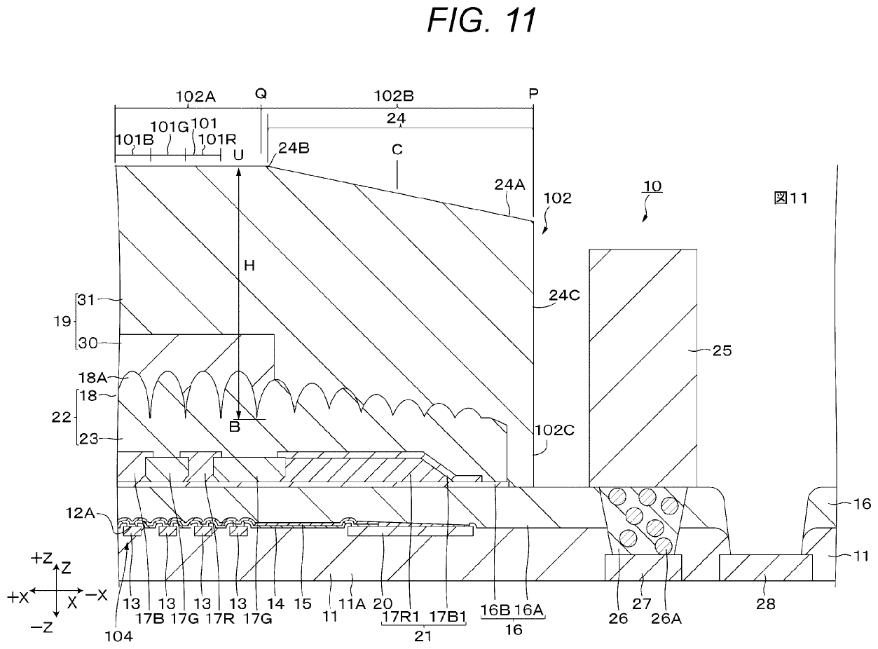

FIG. 12A is a front view illustrating an example of an external appearance of a digital still camera 310. FIG. 12B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center in front of a camera main body (camera body) 311, and a grip 313 to be held by an imager on a front left side.

A monitor 314 is provided at a position shifted to the left from the center of a rear surface of the camera main body 311. An electronic viewfinder (eyepiece window) 315 is provided above the monitor 314. By looking through the electronic viewfinder 315, the photographer can visually confirm a light image of a subject guided from the imaging lens unit 312 and determine a picture composition. As the electronic viewfinder 315, any display device 10 according to one of the above-described embodiments and modification examples thereof may be used.

### Specific Example 2

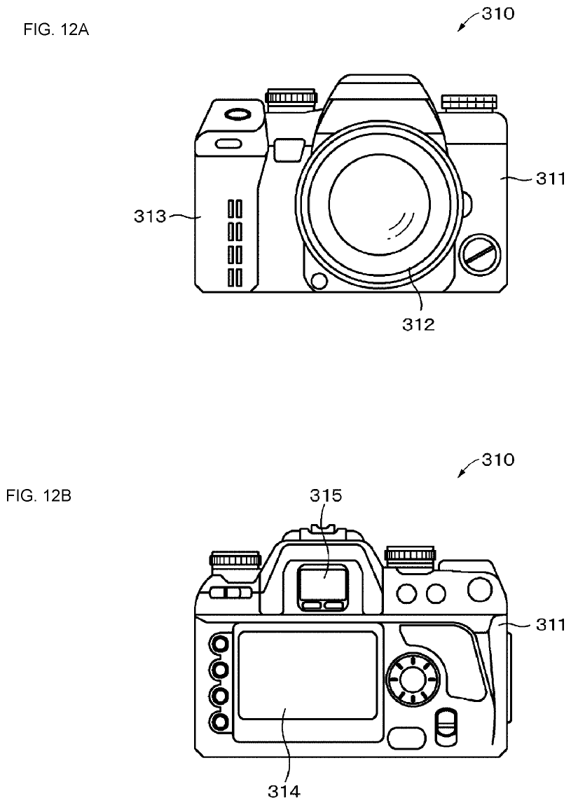

FIG. 13 is a perspective view illustrating an example of an external appearance of a head mounted display 320. The head mounted display 320 includes, for example, ear hooking portions 322 to be worn on the head of the user on both sides of a glass-shaped display unit 321. As the display unit 321, any display device 10 according to one of the above-described embodiments and modification examples thereof may be used.

### Specific Example 3

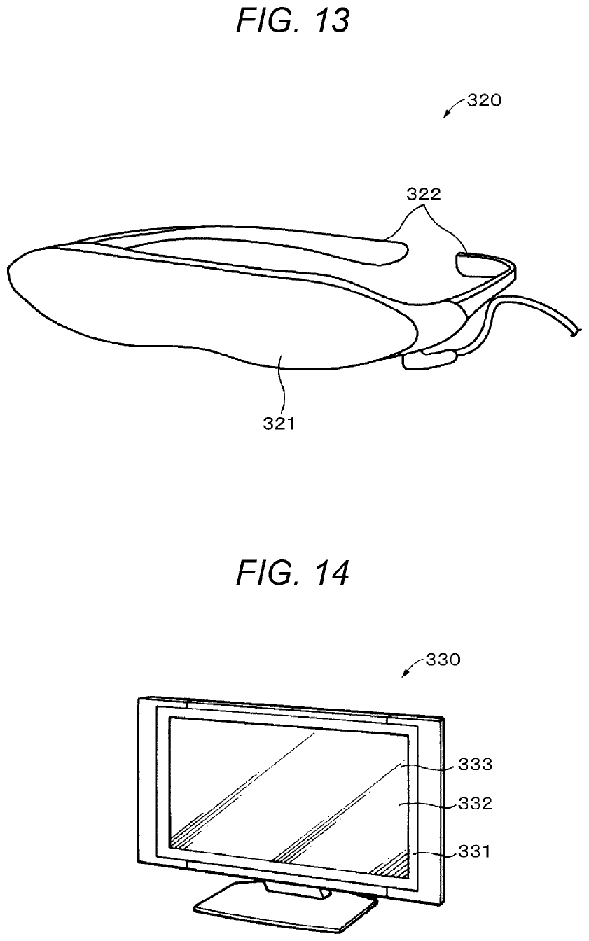

FIG. 14 is a perspective view illustrating an example of an external appearance of the television device 330. The television device 330 includes, for example, a video display screen unit 331 including a front panel 332 and a filter glass 333, and the video display screen unit 331 includes any display device 10 according to one of the above-described embodiments and modifications thereof.

### 7. Illumination Device

The light emitting device according to the present disclosure has been described in detail in the first to fifth embodiments and the modifications described above, taking as an example a case where the light emitting device is a display device. The light emitting device according to the present disclosure is not limited to the display device, and may be used as an illumination device. Even in a case where the light emitting device according to the present disclosure is used as an illumination device, the configurations illustrated in the first to fifth embodiments and the modifications can be adopted.

Although the display device, the application example, and the illumination device according to the first to fifth embodiments and the modifications of the present disclosure have been specifically described above, the present disclosure is not limited to the display device, the application example, and the illumination device according to the first to fifth embodiments and the modifications described above, and various modifications based on the technical idea of the present disclosure are possible.

For example, the configurations, methods, steps, shapes, materials, numerical values, and the like given in the display device, the application example, and the illumination device according to the first to fifth embodiments and the modifications are merely examples, and different configurations, methods, steps, shapes, materials, numerical values, and the like may be used as necessary.

The configurations, methods, steps, shapes, materials, numerical values, and the like of the display device, the application example, and the illumination device according to the first to fifth embodiments and the modifications can be combined with each other without departing from the gist of the present disclosure. The materials exemplified in the display device, the application example, and the illumination device according to the first to fifth embodiments and the modifications can be used alone or in combination of two or more unless otherwise specified.

Furthermore, the present disclosure can also adopt the following configurations.

(1)

A light emitting device including:
a substrate; and
a light emitter including, in order, a light emitting element, a lens layer, and a sealing layer that seals the light emitting element and the lens layer on the substrate,
in which a light emitting region as a region where light generated from the light emitting element is emitted to the outside and a peripheral region as an outer region of the light emitting region are defined,
in a case where a direction along a thickness direction of the light emitter is defined as a line-of-sight direction, and the light emitter is divided into a light emitting unit located in the light emitting region and a peripheral portion located in the peripheral region,
a portion of the peripheral portion including at least a portion of an outer peripheral edge of the peripheral portion forms an inclined portion,
at least a portion of the inclined portion satisfies a condition 1 or 2 and satisfies a condition 3,
the condition 1 is that a thickness of the lens layer in the peripheral portion is smaller than a thickness of the lens layer in the light emitting unit,
the condition 2 is that formation of the lens layer is avoided, and
the condition 3 is that the thickness of the sealing layer in the peripheral portion is smaller than the thickness of the sealing layer in the light emitting unit, and
a refractive index of the lens layer is larger than a refractive index of the sealing layer.
   (2)

The light emitting device according to (1), in which an integrated circuit board that controls a light emission state of the light emitting unit is provided at a position facing an outer end surface of the inclined portion.

(3)

The light emitting device according to (1) or (2), in which the light emitter includes a light shielding layer in the peripheral portion.

(4)

The light emitting device according to (1) or (2), in which the light emitter includes a plurality of color filters corresponding to a plurality of color types, and a light shielding layer is formed in the peripheral portion, and
the light shielding layer has a laminated structure in which the red color filter and the blue color filter are stacked.
   (5)

The light emitting device according to any one of (1) to (4), in which the light emitting element is an organic electroluminescence element.

(6)

The light emitting device according to any one of (1) to (4), in which the light emitting element is a semiconductor light emitting element.

(7)

The light emitting device according to any one of (1) to (6), in which a surface of the inclined portion is an inclined surface inclined downward toward the outer peripheral edge of the peripheral portion.

(8)

The light emitting device according to any one of (1) to (6), in which a surface of the inclined portion is a curved inclined surface inclined downward toward the outer peripheral edge of the peripheral portion.

(9)

The light emitting device according to any one of (1) to (8), in which the inclined portion is formed on the entire outer peripheral edge of the peripheral portion.

(10)

The light emitting device according to any one of (1) to (9), in which the sealing layer has a multilayer structure.

(11)

The light emitting device according to any one of (1) to (9), in which the sealing layer includes an inner layer and an outer layer adjacent to each other, and
a refractive index of the inner layer is larger than a refractive index of the outer layer.
   (12)

The light emitting device according to any one of (1) to (11), in which the lens layer includes a plurality of convex lenses.

(13)

The light emitting device according to any one of (1) to (12), in which the inclined portion satisfies conditions 1 and 3.

(14)

The light emitting device according to (13), in which in the inclined portion, the lens layer has a plurality of lenses, and a distance from a proximal end to a distal end of the lens at a position close to an outer peripheral edge of the peripheral portion is smaller than the distance from the proximal end to the distal end of the lens at a position far from the outer peripheral edge of the peripheral portion.

(15)

The light emitting device according to (13), in which in the inclined portion, the lens layer has a plurality of lenses, and the lens is provided so that the distance from the proximal end to the distal end of the lens decreases gradually toward the outer peripheral edge of the peripheral portion.

(16)

The light emitting device according to any one of (1) to (15), which is of a top emission type.

(17)

A light emitting device including:
a substrate; and
a light emitting element, and a light emitter including a first layer and a second layer in order on a substrate,
in which a light emitting region as a region where light generated from the light emitting element is emitted to the outside and a peripheral region as an outer region of the light emitting region are defined,
in a case where a direction along a thickness direction of the light emitter is defined as a line-of-sight direction, and the light emitter is divided into a light emitting unit located in the light emitting region and a peripheral portion located in the peripheral region,
a portion of the peripheral portion including at least a portion of an outer peripheral edge of the peripheral portion forms an inclined portion,
at least a portion of the inclined portion satisfies a condition 4 or 5 and satisfies a condition 6,
the condition 4 is that a thickness of the first layer in the peripheral portion is smaller than a thickness of the first layer in the light emitting unit,
the condition 5 is that formation of the first layer is avoided, and
the condition 6 is that a thickness of the second layer in the peripheral portion is smaller than the thickness of the second layer in the light emitting unit, and
a refractive index of the first layer is larger than a refractive index of the second layer.
   (18)

An electronic device including the light emitting device according to any one of (1) to (17).

### REFERENCE SIGNS LIST

10 Display device
10A Light emitting region
10B Peripheral region
11 Drive substrate
13 First electrode
14 Organic layer
15 Second electrode
16 Element protective layer
17 Color filter
18 Lens layer
18A Lens
19 Sealing layer
20 Auxiliary electrode
21 Light shielding layer
22 Optical adjustment layer
23 Filter protective layer
24 Inclined portion
24A Inclined surface
24B Proximal end
25 Integrated circuit board
102 Light emitter
102A Light emitting unit
102B Peripheral portion
102C End portion
104 Light emitting element

1. A light emitting device comprising a substrate; and
a light emitter including, in order, a light emitting element, a lens layer, and a sealing layer that seals the light emitting element and the lens layer on the substrate,
wherein a light emitting region as a region where light generated from the light emitting element is emitted to the outside and a peripheral region as an outer region of the light emitting region are defined,
in a case where a direction along a thickness direction of the light emitter is defined as a line-of-sight direction, and the light emitter is divided into a light emitting unit located in the light emitting region and a peripheral portion located in the peripheral region,
at least a portion of the peripheral portion forms an inclined portion,
at least a portion of the inclined portion satisfies conditions 1 or 2 and satisfies a condition 3,
the condition 1 is that a thickness of the lens layer in the peripheral portion is smaller than a thickness of the lens layer in the light emitting unit,
the condition 2 is that formation of the lens layer is avoided, and
the condition 3 is that the thickness of the sealing layer in the peripheral portion is smaller than the thickness of the sealing layer in the light emitting unit, and
a refractive index of the lens layer is larger than a refractive index of the sealing layer.

2. The light emitting device according to claim 1, wherein an integrated circuit board that controls a light emission state of the light emitting unit is provided at a position facing an outer end portion of the inclined portion.

3. The light emitting device according to claim 1, wherein the light emitter includes a light shielding layer in the peripheral portion.

4. The light emitting device according to claim 1, wherein the light emitter includes a plurality of color filters corresponding to a plurality of color types, and a light shielding layer is formed in the peripheral portion, and
the light shielding layer has a laminated structure in which the red color filter and the blue color filter are stacked.

5. The light emitting device according to claim 1, wherein the light emitting element is an organic electroluminescence element.

6. The light emitting device according to claim 1, wherein the light emitting element is a semiconductor light emitting element.

7. The light emitting device according to claim 1, wherein a surface of the inclined portion is an inclined surface inclined downward toward the outer peripheral edge of the peripheral portion.

8. The light emitting device according to claim 1, wherein a surface of the inclined portion is a curved inclined surface inclined downward toward the outer peripheral edge of the peripheral portion.

9. The light emitting device according to claim 1, wherein the inclined portion is formed on the entire outer peripheral edge of the peripheral portion.

10. The light emitting device according to claim 1, wherein the sealing layer has a multilayer structure.

11. The light emitting device according to claim 1, wherein the sealing layer includes an inner layer and an outer layer adjacent to each other, and
a refractive index of the inner layer is larger than a refractive index of the outer layer.

12. The light emitting device according to claim 1, wherein the lens layer includes a plurality of convex lenses.

13. The light emitting device according to claim 1, wherein the inclined portion satisfies the conditions 1 and 3.

14. The light emitting device according to claim 13, wherein in the inclined portion, the lens layer has a plurality of lenses, and a distance from a proximal end to a distal end of the lens at a position close to an outer peripheral edge of the peripheral portion is smaller than the distance from the proximal end to the distal end of the lens at a position far from the outer peripheral edge of the peripheral portion.

15. The light emitting device according to claim 13, wherein in the inclined portion, the lens layer has a plurality of lenses, and the lens is provided so that the distance from the proximal end to the distal end of the lens decreases gradually toward the outer peripheral edge of the peripheral portion.

16. The light emitting device according to claim 1, which is of a top emission type.

17. A light emitting device comprising:
a substrate; and
a light emitter including, in order, a light emitting element, a first layer, and a second layer on the substrate,
wherein a light emitting region as a region where light generated from the light emitting element is emitted to the outside and a peripheral region as an outer region of the light emitting region are defined,
in a case where a direction along a thickness direction of the light emitter is defined as a line-of-sight direction, and the light emitter is divided into a light emitting unit located in the light emitting region and a peripheral portion located in the peripheral region,
at least a portion of the peripheral portion forms an inclined portion,
at least a portion of the inclined portion satisfies a condition 4 or 5 and satisfies a condition 6,
the condition 4 is that a thickness of the first layer in the peripheral portion is smaller than a thickness of the first layer in the light emitting unit,
the condition 5 is that formation of the first layer is avoided,
the condition 6 is that the thickness of the second layer in the peripheral portion is smaller than the thickness of the second layer in the light emitting unit, and
a refractive index of the first layer is larger than a refractive index of the second layer.

18. An electronic device comprising the light emitting device according to claim 1.
